(19) United States
(12) Patent Application Publication
(10) Pub. No.: US 2025/0261314 A1
(43) Pub. Date: Aug. 14, 2025

(54) SUBSTRATE WITH BUILT-IN ELECTRONIC COMPONENTS

(71) Applicant: Murata Manufacturing Co., Ltd., Kyoto (JP)

(72) Inventors: Hidehiko SASAKI, Kyoto (JP); Atsushi SAKURAI, Kyoto (JP)

(21) Appl. No.: 19/190,869

(22) Filed: Apr. 28, 2025

Related U.S. Application Data
(63) Continuation of application No. PCT/JP2023/023985, filed on Jun. 28, 2023.

(30) Foreign Application Priority Data
Dec. 27, 2022 (JP) 2022-209704

(51) Int. Cl. H05K 1/18; H05K 1/11

(52) U.S. Cl. CPC H05K 1/185; H05K 1/115; H05K 2201/10522

(57) ABSTRACT

A substrate with built-in electronic components includes an insulator having a first surface and a second surface facing away from the first surface, and a plurality of electronic components built into the insulator, in which each of the electronic components includes a first electrode disposed in a first direction toward the first surface of the insulator and a second electrode disposed in a second direction opposite to the first direction, the electronic components is rectangular in top view from a first surface side, and rectangles of the plurality of electronic components on the first surface side in top view from the first surface side are irregularly disposed.

### CROSS REFERENCE TO RELATED APPLICATION

This is a continuation of International Application No. PCT/JP2023/023985 filed on Jun. 28, 2023 which claims priority from Japanese Patent Application No. 2022-209704 filed on Dec. 27, 2022. The contents of these applications are incorporated herein by reference in their entireties.

### BACKGROUND OF THE DISCLOSURE

### Field of the Disclosure

The present disclosure relates to a substrate with built-in electronic components.

### Description of the Related Art

Patent Document 1 describes a substrate with built-in components that includes a plurality of electronic components. FIGS. 6A and 6B of Patent Document 1 disclose a two-dimensional arrangement of four electronic components in first and second directions of a multilayer body.

Patent Document 1: International Publication No. 2017/199825

### BRIEF SUMMARY OF THE DISCLOSURE

When the structure as described in Patent Document 1 includes a plurality of electronic components, since the strength of the substrate including the plurality of electronic components may be lower than that of the substrate including no electronic components, the strength of the substrate with built-in electronic components needs to be increased.

The present disclosure addresses the problem described above with a possible benefit of providing a substrate with built-in electronic components having high strength.

A substrate with built-in electronic components according to the present disclosure includes: an insulator having a first surface and a second surface facing away from the first surface; and a plurality of electronic components built into the insulator, in which each of the electronic components includes a first electrode disposed in a first direction toward the first surface of the insulator and a second electrode disposed in a second direction opposite to the first direction, the electronic components are rectangular in top view from a first surface side, and rectangles of the plurality of electronic components in top view from the first surface side are irregularly disposed.

According to the present disclosure, a high-strength substrate with built-in electronic components can be provided.

### BRIEF DESCRIPTION OF THE SEVERAL VIEWS OF THE DRAWINGS

FIG. 1 is a sectional view schematically illustrating an example of a substrate with built-in electronic components according to an embodiment of the present disclosure.

FIG. 2 is a top view of the substrate with built-in electronic components illustrated in FIG. 1 as seen from a first surface side.

FIG. 3 is a top view of an insulating substrate that is an insulator as seen from the first surface side and this drawing is used to describe the angles formed by an axis parallel to a direction in which the electronic components are arranged and sides of the electronic components.

FIG. 4 is a top view from the first surface side schematically illustrating an example in which the plurality of electronic components are staggered.

FIG. 5 is a top view schematically illustrating an example in which the cavities are rectangular in top view from the first surface side.

FIG. 6 is a top view schematically illustrating an example in which the insulator is an encapsulating material having no cavity in top view from the first surface side.

FIG. 7A is a process diagram schematically illustrating an example of a manufacturing process of the substrate with built-in electronic components.

FIG. 7B is a process diagram schematically illustrating the example of the manufacturing process of the substrate with built-in electronic components.

FIG. 7C is a process diagram schematically illustrating the example of the manufacturing process of the substrate with built-in electronic components.

FIG. 7D is a process diagram schematically illustrating the example of the manufacturing process of the substrate with built-in electronic components.

FIG. 8A is a process diagram schematically illustrating the example of the manufacturing process of the substrate with built-in electronic components.

FIG. 8B is a process diagram schematically illustrating the example of the manufacturing process of the substrate with built-in electronic components.

FIG. 8C is a process diagram schematically illustrating the example of the manufacturing process of the substrate with built-in electronic components.

FIG. 9A is a process diagram schematically illustrating another example of the manufacturing process of the substrate with built-in electronic components.

FIG. 9B is a process diagram schematically illustrating the other example of the manufacturing process of the substrate with built-in electronic components.

FIG. 9C is a process diagram schematically illustrating the other example of the manufacturing process of the substrate with built-in electronic components.

FIG. 9D is a process diagram schematically illustrating the other example of the manufacturing process of the substrate with built-in electronic components.

FIG. 10A is a process diagram schematically illustrating the other example of the manufacturing process of the substrate with built-in electronic components.

FIG. 10B is a process diagram schematically illustrating the other example of the manufacturing process of the substrate with built-in electronic components.

FIG. 10C is a process diagram schematically illustrating the other example of the manufacturing process of the substrate with built-in electronic components.

### DETAILED DESCRIPTION OF THE DISCLOSURE

A substrate with built-in electronic components according to the present disclosure will be described below.

However, the present disclosure is not limited to the following structure and can be applied by being changed as appropriate without departing from the spirit of the present disclosure. It should be noted that a combination of two or more of the desirable structures described below is also included in the present disclosure.

### Substrate with Built-In Electronic Components

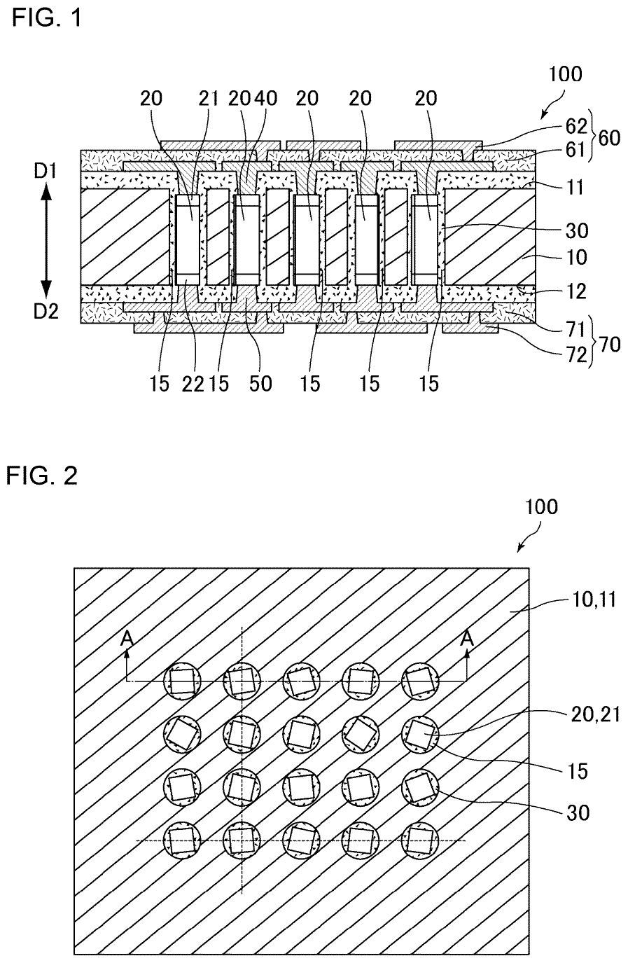

FIG. 1 is a sectional view schematically illustrating an example of a substrate with built-in electronic components according to an embodiment of the present disclosure.

FIG. 2 is a top view of the substrate with built-in electronic components illustrated in FIG. 1 as seen from a first surface side. In FIG. 2, components that cover first electrodes of electronic components are not illustrated so that the first electrodes can be seen.

In addition, FIG. 1 is a sectional view taken along line A-A illustrated in FIG. 2.

A substrate 100 with built-in electronic components illustrated in FIGS. 1 and 2 includes an insulating substrate 10 as an insulator including a first surface 11 and a second surface 12 facing away from the first surface 11 and a plurality of electronic components 20 included in the insulating substrate 10.

Each of the electronic components 20 includes a first electrode 21 disposed in a first direction DI toward the first surface 11 of the insulating substrate 10 and a second electrode 22 in a second direction D2 opposite to the first direction D1.

Portions between the electronic components 20 and the insulating substrate 10 are encapsulated with an encapsulating material 30.

On a first surface 11 side, first via conductors 40 electrically connected to first electrodes 21 of the electronic components 20 are provided, and a first buildup layer (rewiring layer) 60 including a conductor wiring 62 and an insulating layer 61 is further provided.

On a second surface 12 side, second via conductors 50 electrically connected to second electrodes 22 of the electronic components 20 are provided, and a second buildup layer (rewiring layer) 70 including a conductor wiring 72 and an insulating layer 71 is further provided.

The insulating substrate 10 may be a resin substrate, a glass substrate, a ceramic substrate, or the like. The insulating substrate 10 may be a printed wiring board on or in which a conductor wiring is provided. The insulating substrate 10 may be an insulating support substrate (core material) formed of a resin, such as an epoxy resin, and a reinforcing material, such as glass cloth. The supporting substrate may contain inorganic particles, such as silica particles or alumina particles.

The first surface 11 and the second surface 12 of the insulating substrate 10 are parallel to each other and constitute a pair of main surfaces of the insulating substrate 10 that face away from each other.

In the substrate 100 with built-in electronic components according to the embodiment illustrated in FIG. 1, the insulating substrate 10 has cavities 15, and one electronic component is disposed in each of the cavities 15. In FIG. 1, a total of five electronic components 20 are disposed in the five cavities 15 (one for each). In the cavity 15, a portion between the electronic component 20 and the insulating substrate 10 is encapsulated with the encapsulating material 30, and the position of the electronic component 20 is fixed in the cavity 15.

The electronic component 20 is not particularly limited and may be a passive component, such as a capacitor (for example, a multilayer ceramic capacitor (MLCC)), or an inductor. The electronic component 20 is a chip component having a rectangular parallelepiped longitudinal shape.

In addition, the dimension of the electronic component 20 in a direction (the first direction D1 or the second direction D2) orthogonal to the second surface 12 of the insulating substrate 10 may be larger than the dimension in a direction parallel to the second surface 12. As a result, the electronic components 20 can be disposed more densely.

Only one type of the electronic components 20 may be disposed in the substrate 100 with built-in electronic components or two or more types of the electronic components 20 may be disposed (in a mixed manner).

In addition, the number of the electronic components 20 disposed in the substrate 100 with built-in electronic components is not particularly limited and may be, for example, three or more. Alternatively, the number of the electronic components 20 may be 1000 or less.

In FIG. 2, in top view from a first surface 11 side, the cavities 15 are circular, and one electronic component 20 is disposed in each of the cavities 15.

The electronic components 20 are rectangular in top view from the first surface 11 side. The electronic components 20 may be rectangular or square in top view, and, in FIG. 2, the electronic components 20 are square in top view from the first surface 11 side.

In FIG. 2, the plurality of electronic components 20 are disposed in a grid pattern in top view from the first surface 11 side. When the centers of rectangles are disposed in a grid pattern, it is determined that the electronic components are disposed in a grid pattern. In addition, in FIG. 2, the center-to-center distances between the plurality of electronic components 20 are substantially identical to each other.

It should be noted that the center of the rectangle coincides with the intersection of the diagonals of the rectangle.

One criterion for determining that the center-to-center distances between the plurality of electronic components are substantially identical to each other is that the ratio of measurement values that fall outside 80% to 120% of the average value of the center-to-center distances measured at a plurality of positions to all measurement values is 10% or less.

In FIG. 2, the rectangles of the plurality of electronic components 20 are irregularly oriented in top view from the first surface 11 side.

Since the electronic components are not aligned with each other when the rectangles of the electronic components are irregularly oriented, the stress applied to the substrate with built-in electronic components due to thermal expansion or the like is not concentrated in a specific direction. Accordingly, the strength of the substrate with built-in electronic components increases.

In addition, when the rectangles of the electronic components are irregularly oriented, the area of the insulator between adjacent electronic components in top view becomes large or small. Since the strength and the rigidity of a portion of the substrate having a large area increase, the substrate with built-in electronic components is suppressed from warping.

The angle formed by the axis parallel to a direction in which the electronic components are arranged and one side of each of the electronic components of the substrate with built-in electronic components will be described.

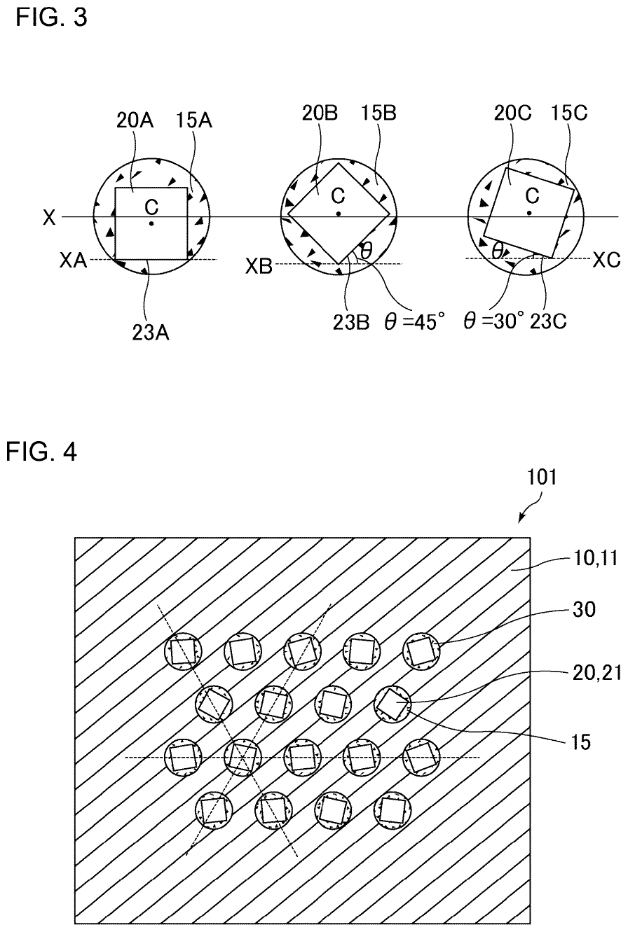

FIG. 3 is a top view of the insulating substrate that is an insulator as seen from the first surface side, and this drawing is used to describe the angles formed by the axis parallel to the direction in which the electronic components are arranged and sides of the electronic components.

In FIG. 3, an electronic component 20A, an electronic component 20B, and an electronic component 20C are disposed in a cavity 15A, a cavity 15B, and a cavity 15C, respectively.

Centers C of rectangles of the electronic components on the first surface side are determined, and an axis is determined such that as many centers C of the rectangles as possible are arranged near the axis. An axis X parallel to the direction in which the electronic components are arranged can be determined by converting the positions of the centers C into coordinates and drawing an approximate straight line by using a least squares method.

When the plurality of electronic components are disposed in a grid pattern as illustrated in FIG. 2, the centers C of the rectangles are also disposed in a grid pattern. In this case, the axis X can be drawn in the horizontal direction or the vertical direction. In FIG. 2, an example of axes in the horizontal direction and in the vertical direction are indicated by dotted lines.

An angle θ formed by the axis X determined as described above and one side of the electronic component (one side of the rectangle) is obtained. The angle θ is the most acute angle of the angles formed by the axis X and any one side of the electronic component. The angle formed by the axis X and one side of the electronic component is not the angle at a position at which the axis X intersects a side of the electronic component but the angle formed by a straight line parallel to the axis X and a side that forms the smallest angle.

When one side of the electronic component is parallel to the axis X, the angle θ is 0°.

The electronic component 20A is an example in which the angle (not illustrated as θ) formed by a straight line XA that is parallel to the axis X and indicated by a dotted line and a side 23A is 0°.

The maximum value of the angle θ is 45°. The electronic component 20B is an example in which the angle formed by a straight line XB that is parallel to the axis X and indicated by a dotted line and a side 23B is 45°.

In addition, the electronic component 20C is an example in which the angle formed by a straight line XC that is parallel to the axis X and indicated by a dotted line and a side 23C is neither the maximum value nor the minimum value but, for example, 30°.

When the angle formed by the axis parallel to the direction in which the electronic components are arranged and a side of each of the electronic components is determined, there may be a point at which the angle differs between adjacent electronic components.

In FIG. 3, the electronic component 20A and the electronic component 20B are adjacent electronic components, and the angle formed by the axis parallel to the direction in which the electronic components are arranged and a side of each of the electronic components differs between adjacent electronic components. In addition, the electronic component 20B and the electronic component 20C are adjacent electronic components, and the angle formed by the axis parallel to the direction in which the electronic components are arranged and a side of each of the electronic components differs between adjacent electronic components.

When the angle formed by the axis parallel to the direction in which the electronic components are arranged and a side of each of the electronic components is determined, the average angle of the angles formed by the axis and one side of each of the electronic components may be 5° or more and 40° or less.

When many electronic components are disposed in top view from the first surface 11 side as illustrated in FIG. 2, the angle formed by the axis and a side of each of the electronic components is obtained for the electronic components, and the average value is obtained. The number of the electronic components used to obtain the average value of the angles may be three or more.

When the angle formed by the axis parallel to the direction in which the electronic components are arranged and one side of each of the electronic components is determined, there may be a point at which the difference in the angle formed by the axis and one side of each of the electronic components between adjacent electronic components may be 5° or more and 45° or less.

When such a condition is met, the rectangles of the plurality of electronic components on the first surface side are irregularly oriented.

For example, since angle θ of the electronic component 20A is 0° and angle θ of the electronic component 20B is 45° in FIG. 3, the difference in the angle formed by the axis and one side of each of the electronic components between adjacent electronic components is 45°. Since angle e of the electronic component 20B is 45° and angle θ of the electronic component 20C is 30°, the difference in the angle formed by the axis and one side of each of the electronic components between adjacent electronic components is 15°. In this case, regarding the three electronic components 20A, 20B, and 20C, there are two points at which the difference in the angle formed by the axis and one side of each of the electronic components is 5° or more and 45° or less between adjacent electronic components.

When the angle formed by the axis parallel to the direction in which the electronic components are arranged and one side of each of the electronic components is determined, the standard deviation of the angle formed by the axis and one side of each of the electronic components may be 5° or more.

The standard deviation of the angle can be used as one indicator of variations in the orientations of the rectangles of the electronic components on the first surface side. When the standard deviation is 0°, all rectangles of the electronic components on the first surface side are aligned. The number of electronic components used to obtain the standard deviation of the angle may be three or more.

When the plurality of electronic components are closely disposed in the substrate with built-in electronic components, the strength of the substrate with built-in electronic components is likely to decrease disadvantageously. Accordingly, in the plurality of electronic components closely disposed in the substrate with built-in electronic components, the effects of the structure according to the present disclosure are more likely to be achieved. An example of the structure in which the plurality of electronic components are closely disposed will be described below.

Size of electronic component: 0603 size

Center-to-center distance between electronic components: 0.50 mm or more and 0.75 mm or less, specifically 0.65 mm

Area ratio of electronic components in top view from the first surface side: 30% or more and 50% or less, specifically 37%

In addition, when the insulator has cavities and one electronic component is disposed in each of the cavities, the shortest distance between the inner circumference of the cavity and the electronic component may be 50 μm or more and 150 μm or less. It should be noted that the preferred range of the shortest distance described above is an example of the preferred range when the electronic component has 0603 size, and the size of the cavities and the preferred optimal range of the shortest distance depend on the size of the electronic components. For example, the shortest distance between the inner circumference of the cavity and the electronic component may be ⅙ or more and ½ or less of the length of the short side of the rectangular electronic component.

When the shortest distance between the inner circumference of the cavity and the electronic component is determined, the point at which the distance between the inner circumference of the cavity and the electronic component is shortest is selected with the center of the circle of the cavity aligned with the center of the rectangle of the electronic component in top view.

When the shortest distance between the inner circumference of the cavity and the electronic component is short, the position of the center of the rectangle of the electronic component on the first surface side is determined with high accuracy. Accordingly, a via conductor is connected to the center of the first electrode on the first surface side with high positional accuracy. Similarly, since the position of the center of the rectangle of the electronic component on a second surface side is determined with high accuracy, a via conductor is connected to the center of the second electrode on the second surface side with high positional accuracy.

Other components that can be included in the substrate with built-in electronic components will be described with reference to FIG. 1.

The encapsulating material 30 is a member with which the electronic components 20 are encapsulated in the cavities 15 and fills portions around the electronic components 20 in the cavities 15. The encapsulating material 30 may contain a resin, such as an epoxy resin, and a filler including inorganic particles, such as silica particles and alumina particles.

The encapsulating material may be, for example, an ABF film (manufactured by Ajinomoto Fine-Techno Co., Inc.).

At least one first via conductor 40 is provided in each of the electronic components 20, and the first electrode 21 of each of the electronic components 20 is electrically connected to the first buildup layer 60 via the first via conductor 40.

At least one second via conductor 50 is provided in each of the electronic components 20, and the second electrode 22 of each of the electronic components 20 is electrically connected to the second buildup layer 70 via the second via conductor 50.

The first buildup layer 60 electrically connects the electronic components 20 to each other, the electronic component 20 to other components, through-holes, terminals, or the like. In the first buildup layer 60, at least one insulating layer 61 and at least one conductor wiring 62 are stacked alternately.

Similarly, the second buildup layer 70 electrically connects the electronic components 20 to each other, the electronic component 20 to other components, through-holes, terminals, or the like. In the second buildup layer 70, at least one insulating layer 71 and at least one conductor wiring 72 are stacked alternately.

In the substrate with built-in electronic components, a via conductor may be connected to the center of the upper surface of the first electrode on the first surface side and/or to the center of the bottom surface of the second electrode on the second surface side. In the substrate 100 with built-in electronic components illustrated in FIG. 1, the first via conductor 40 is connected to the center of the upper surface of the first electrode 21 on the first surface side, and the second via conductor 50 is connected to the center of the upper surface of the second electrode 22 on the second surface side.

### Modifications of Substrate with Built-In Electronic Components

FIG. 4 is a top view schematically illustrating an example in which the plurality of electronic components are staggered as seen from the first surface side. As in FIG. 2, components that cover the first electrodes of the electronic components are not illustrated so that the first electrodes can be seen.

In the substrate 101 with built-in electronic components illustrated in FIG. 4, the plurality of electronic components 20 are staggered in top view from the first surface 11 side. When the centers of the rectangles are staggered, it is determined that the electronic components are staggered. In addition, the center-to-center distances between the plurality of electronic components 20 are substantially identical to each other. The structure of the substrate 101 with built-in electronic components is the same as the substrate 100 with built-in electronic components illustrated in FIG. 2 with the exception of the disposition of the plurality of electronic components 20.

Also in the substrate 101 with built-in electronic components illustrated in FIG. 4, as in the case described with reference to FIGS. 2 and 3, in top view from the first surface 11 side, the rectangles of the plurality of electronic components 20 on the first surface 11 side are irregularly oriented.

When the plurality of electronic components are staggered as illustrated in FIG. 4, the centers of the rectangles are also staggered. In this case, the axes are drawn in the horizontal direction or in a diagonal direction (the direction in which the electronic components are arranged in a line). In FIG. 4, an example of axes in the horizontal direction and in the diagonal directions is indicated by dotted lines.

The angle formed by the axis parallel to the direction in which the electronic components are arranged and a side of the electronic components can be determined by using the axis drawn as described above, as in the case described with reference to FIG. 3. A preferred aspect determined by using the angles is the same as the case in which the plurality of electronic components are disposed in a grid pattern.

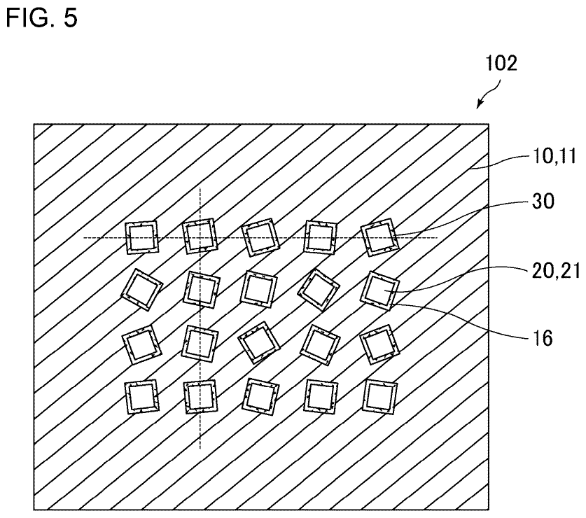

FIG. 5 is a top view schematically illustrating an example in which the cavities are rectangular in top view from the first surface side. As in FIG. 2, components that cover the first electrodes of the electronic components are not illustrated so that the first electrodes can be seen.

In the substrate 102 with built-in electronic components illustrated in FIG. 5, the cavities 16 are rectangular in top view from the first surface 11 side, and one electronic component 20 is disposed in each of the cavities 16.

The rectangle of the cavity 16 may be similar to the rectangle of the electronic component 20 in top view, and the rectangle of the cavity 16 is one size larger than the rectangle of the electronic component 20 in top view. For example, the similarity ratio of the rectangle of the cavity to the rectangle of the electronic component (the rectangle of the cavity/the rectangle of the electronic component) in top view may be 1.05 or more and 1.30 or less.

In addition, the shortest distance between the inner circumference of the cavity and the electronic component may be 50 μm or more and 150 μm or less. When the shortest distance between the inner circumference of the cavity and the electronic component is determined, the point at which the distance between the inner circumference of the cavity and the electronic component is shortest is selected with the center of the rectangle of the cavity aligned with the center of the rectangle of the electronic component in top view. It should be noted that the preferred range of the shortest distance described above is an example of the preferred range when the size of the electronic component is 0603 size, and the size of the cavities and the preferred optimal range of the shortest distance depend on the size of the electronic components. For example, the shortest distance between the inner circumference of the cavity and the electronic component may be ⅙ or more and ½ or less of the length of the short side of the rectangular electronic component.

When the cavities are rectangular and the rectangles of the cavities are relatively larger than the rectangles of the electronic components in top view, the positions of the electronic components in the cavities vary to some extent. In contrast, when the rectangles of the cavities are substantially the same as the rectangles of the electronic components in top view, the positions of the electronic components in the cavities are substantially fixed.

In the substrate 102 with built-in electronic components in which the cavities 16 are rectangular, when the cavities 16 are irregularly oriented, the orientation of the rectangles of the electronic components 20 in top view is determined by the orientation of the rectangles of the cavities 16, and accordingly, the rectangles of the electronic components 20 in top view are irregularly oriented.

The cavities 16 are irregularly oriented in the substrate 102 with built-in electronic components illustrated in FIG. 5, but the centers of the rectangles of the cavities 16 are disposed in a grid pattern. The centers of the rectangles of the electronic components 20 in top view disposed in the cavities 16 are also disposed in a grid pattern. Axes can be obtained in accordance with the centers of the rectangles of the electronic components 20 in top view. In FIG. 5, an example of axes in the vertical direction and in the horizontal direction is indicated by dotted lines.

The angle formed by the axis parallel to the direction in which the electronic components are arranged and a side of each of the electronic components can be determined by using the axes drawn as described above, as in the case described with reference to FIG. 3. A preferred aspect determined by using the angles is the same as the case in which the cavities are circular.

The insulator need not be an insulating substrate having cavities and may be an encapsulating material. In this case, the encapsulating material need not have cavities.

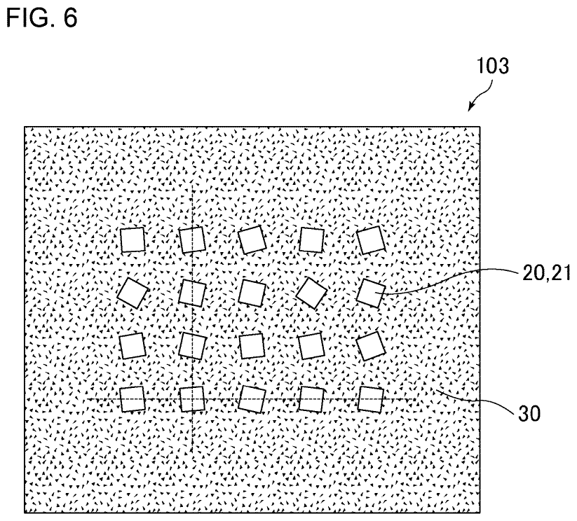

FIG. 6 is a top view schematically illustrating an example in which the insulator is an encapsulating material having no cavities in top view from the first surface side. As in FIG. 2, components that cover the first electrodes of the electronic components are not illustrated so that the first electrodes can be seen.

In the substrate 103 with built-in electronic components illustrated in FIG. 6, the plurality of electronic components 20 are disposed in the encapsulating material 30 having no cavities. The plurality of electronic components may be disposed in a grid pattern, a staggered pattern, or any other pattern.

Also in the substrate 103 with built-in electronic components illustrated in FIG. 6, as in the case described with reference to FIGS. 2 and 3, the rectangles of the plurality of electronic components 20 on the first surface 11 side are irregularly oriented in top view from the first surface 11 side.

In the substrate 103 with built-in electronic components illustrated in FIG. 6, the centers of the rectangles of the electronic components 20 in top view are disposed in a grid pattern. Axes can be obtained in accordance with the centers of the rectangles of the electronic components 20 in top view. In FIG. 6, an example of axes in the vertical direction and in the horizontal direction is indicated by dotted lines.

The angle formed by the axis parallel to the direction in which the electronic components are arranged and a side of each of the electronic components can be determined by using the axes drawn as described above, as in the case described with reference to FIG. 3. A preferred aspect determined by using the angles is the same as the case in which the electronic components are disposed in the cavities of the insulating substrate.

### Manufacturing Method of Substrate with Built-In Electronic Components

The manufacturing method of the substrate with built-in electronic components will be described below.

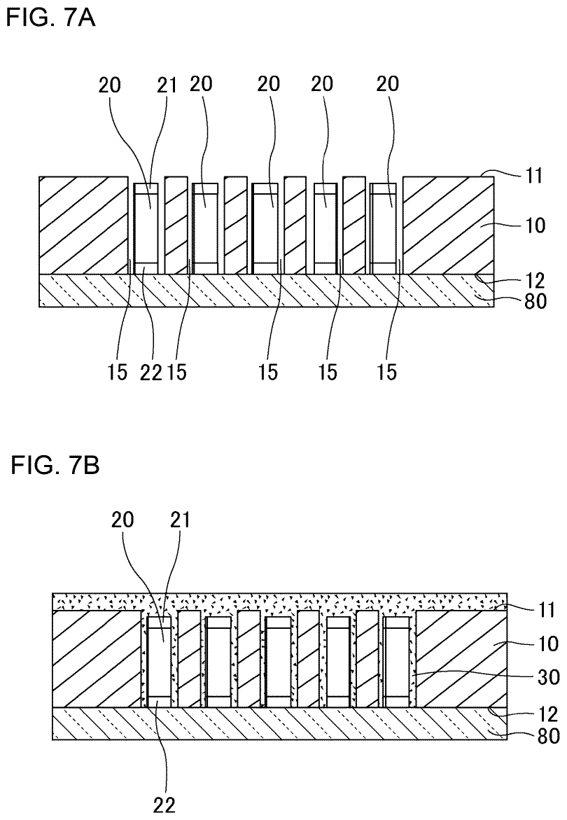

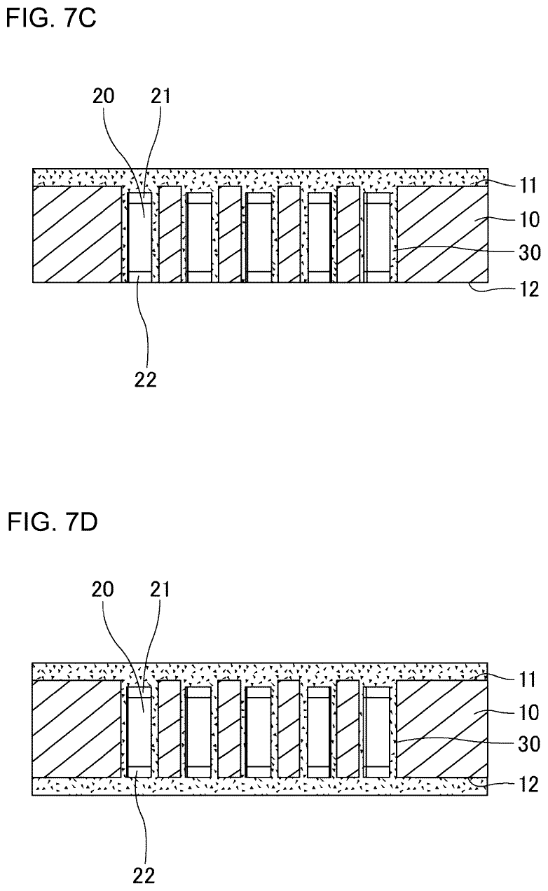

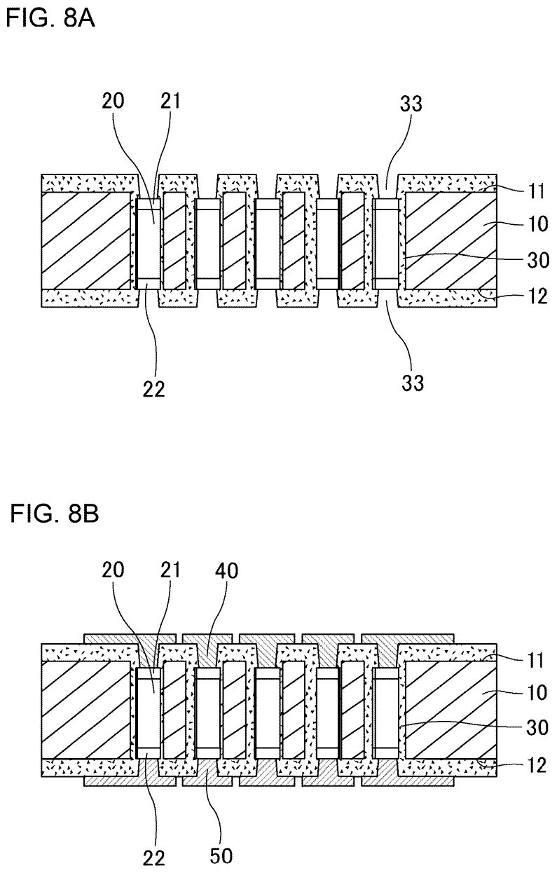

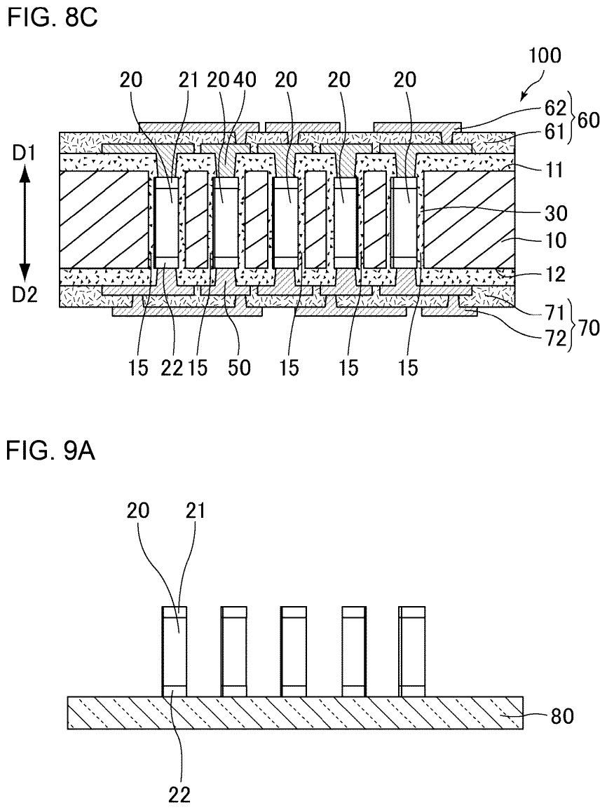

FIGS. 7A, 7B, 7C, 7D, 8A, 8B, and 8C are process diagrams schematically illustrating an example of a manufacturing process of the substrate with built-in electronic components.

The process described below is a process for manufacturing the substrate with built-in electronic components (embodiments illustrated in FIGS. 2, 4, and 5) in which cavities are formed in the insulating substrate that is an insulator, and one electronic component is disposed in each of the cavities.

As illustrated in FIG. 7A, the insulating substrate 10 having the cavities 15 at predetermined positions is prepared, the insulating substrate 10 is pasted onto an adhesive sheet 80, and the electronic components 20 are disposed in the cavities 15.

The electronic components 20 stand in the cavities without falling by being pasted onto the adhesive sheet 80. The adhesive sheet 80 may be a thermally foamed sheet.

As illustrated in FIG. 7B, the cavities 15 are encapsulated with the encapsulating material 30, and the first surface 11 of the insulating substrate 10 is covered with the encapsulating material 30. The encapsulating material 30 can be provided in the cavities 15 and on the first surface 11 of the insulating substrate 10 by vacuum lamination. Next, the encapsulating material 30 is cured by being heated. The heating temperature is, for example, 180° C.

As illustrated in FIG. 7C, the adhesive sheet 80 that is a thermally foamed sheet is heated at a peeling temperature (for example, 200° C.) or higher to lose the adhesive strength of the adhesive sheet 80, and the adhesive sheet 80 is removed.

As illustrated in FIG. 7D, the second surface 12 of the insulating substrate 10 is also covered with the encapsulating material 30. The encapsulating material 30 can be provided on the second surface 12 of the insulating substrate 10 by vacuum lamination. Next, the encapsulating material 30 is cured by being heated. The heating temperature is, for example, 180° C.

As illustrated in FIG. 8A, via holes 33 are formed by applying a laser to the encapsulating material 30 on the first surface 11 and the second surface 12 of the insulating substrate 10. The via holes 33 are formed at positions at which the first electrode 21 and the second electrode 22 of the electronic component 20 are exposed therethrough. The laser may be, for example, a CO₂ laser.

As illustrated in FIG. 8B, the first via conductors 40 electrically connected to the first electrodes 21 of the electronic components 20 are provided. The second via conductors 50 electrically connected to the second electrodes 22 of the electronic components 20 are provided.

The first via conductors 40 and the second via conductors 50 can be formed by conductive paste printing, metal plating, or the like.

As illustrated in FIG. 8C, the first buildup layer (rewiring layer) 60 including the conductor wiring 62 and the insulating layer 61 is further provided on the first surface 11 of the insulating substrate 10. In addition, the second buildup layer (rewiring layer) 70 including the conductor wiring 72 and the insulating layer 71 is provided on the second surface 12 of the insulating substrate 10.

The first buildup layer 60 and the second buildup layer 70 can be formed by, for example, plating (for example, a semi-additive method).

The substrate 100 with built-in electronic components in which the insulating substrate 10 has the cavities 15 and one electronic component 20 is disposed in each of the cavities 15 can be manufactured by the process described above.

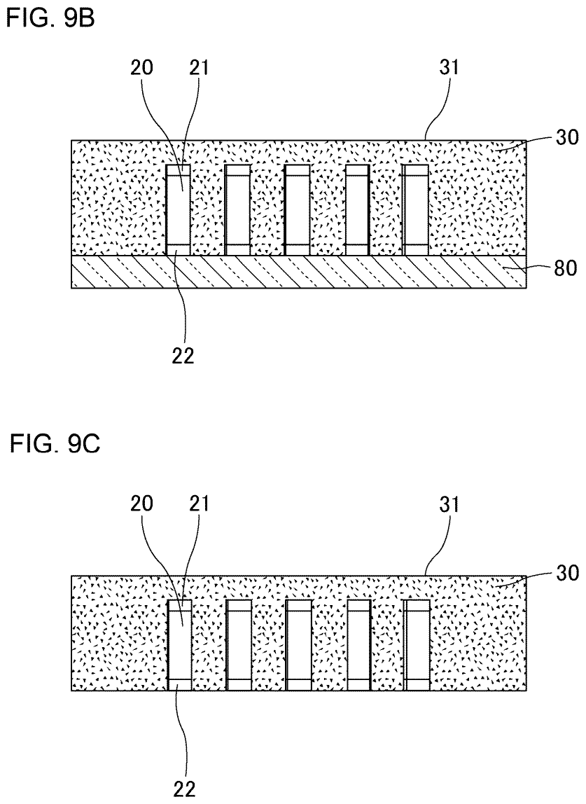

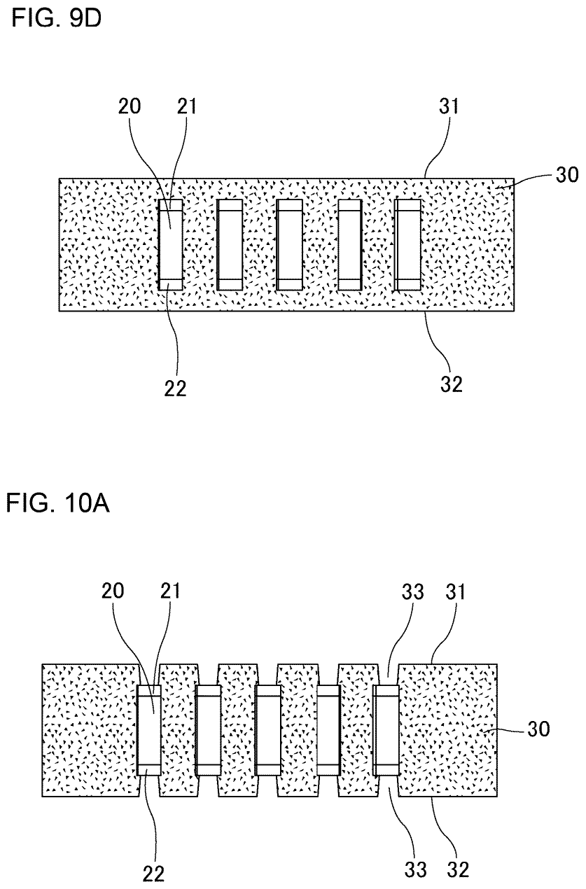

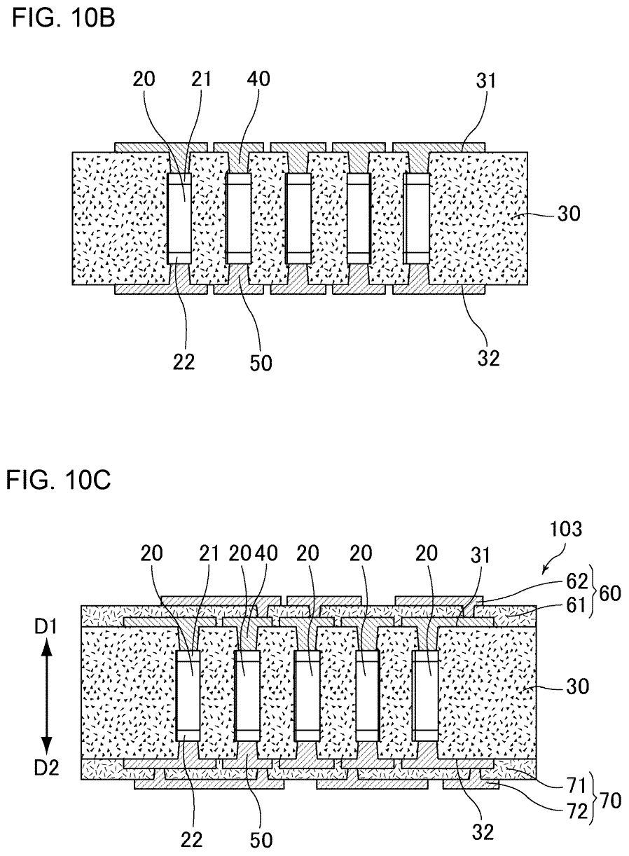

FIGS. 9A, 9B, 9C, 9D, 10A, 10B, and 10C are process diagrams schematically illustrating another example of the manufacturing process of the substrate with built-in electronic components.

The process of manufacturing the substrate with built-in electronic components (the embodiment illustrated in FIG. 6) in which the insulator is the encapsulating material having no cavities will be described below.

As illustrated in FIG. 9A, the electronic components 20 are pasted and disposed at predetermined positions on the adhesive sheet 80.

The adhesive sheet 80 may be a thermally foamed sheet.

As illustrated in FIG. 9B, the electronic components 20 are encapsulated with the encapsulating material 30. The encapsulating material 30 can be formed by vacuum lamination. Next, the encapsulating material 30 is cured by being heated. The heating temperature is, for example, 180° C.

As illustrated in FIG. 9C, the adhesive sheet 80 that is a thermally foamed sheet is heated at a peeling temperature (for example, 200° C.) or higher to lose its adhesive strength, and the adhesive sheet 80 is removed.

As illustrated in FIG. 9D, the second electrodes 22 of the electronic components 20 are covered with the encapsulating material 30. The encapsulating material 30 can be provided on the second electrode 22 of the electronic components. Next, the encapsulating material 30 is cured by being heated. The heating temperature is, for example, 180° C.

A main surface of the encapsulating material 30 on the first electrode 21 side of the electronic component 20 is a first surface 31 of the encapsulating material, and a main surface of the encapsulating material 30 on the second electrode 22 side of the electronic component 20 is a second surface 32 of the encapsulating material. This encapsulating material 30 is an insulator that includes a first surface 31 and a second surface 32 facing away from a first surface 31.

As illustrated in FIG. 10A, the via holes 33 are formed by applying a laser to the encapsulating material 30 on the first surface 31 and the second surface 32 of the encapsulating material 30. The via holes 33 are formed at positions at which the first electrode 21 and the second electrode 22 of the electronic component 20 are exposed therethrough. The laser may be, for example, a CO₂ laser.

As illustrated in FIG. 10B, the first via conductors 40 electrically connected to the first electrodes 21 of the electronic components 20 are provided. The second via conductors 50 electrically connected to the second electrodes 22 of the electronic components 20 are provided.

The first via conductors 40 and the second via conductors 50 can be formed by conductive paste printing, metal plating, or the like.

As illustrated in FIG. 10C, the first buildup layer (rewiring layer) 60 including the conductor wiring 62 and the insulating layer 61 is further provided on the first surface 31 of the encapsulating material 30. In addition, the second buildup layer (rewiring layer) 70 including the conductor wiring 72 and the insulating layer 71 is provided on the second surface 32 of the encapsulating material 30.

The first buildup layer 60 and the second buildup layer 70 can be formed by, for example, plating (for example, a semi-additive method).

The substrate 103 with built-in electronic components in which the insulator has no cavities can be manufactured by the process described above.

The following aspects are disclosed in this specification.

<1>

A substrate with built-in electronic components, comprising: an insulator having a first surface and a second surface facing away from the first surface; and a plurality of electronic components built into the insulator, wherein each of the electronic components includes a first electrode disposed in a first direction toward the first surface of the insulator and a second electrode disposed in a second direction opposite to the first direction, the electronic components are rectangular in top view from a first surface side, and rectangles of the plurality of electronic components in top view from the first surface side are irregularly disposed.

<2>

The substrate with built-in electronic components according to <1>, wherein, when an axis parallel to a direction in which the plurality of electronic components are arranged in top view from the first surface side is determined, there is a point at which an angle formed by the axis and one side of each of the electronic components differs between adjacent electronic components of the plurality of electronic components.

<3>

The substrate with built-in electronic components according to <1> or <2>, wherein, when the axis parallel to the direction in which the plurality of electronic components are arranged in top view from the first surface side is determined, an average angle of angles formed by the axis and the one side of each of the electronic components is 5° or more and 40° or less.

<4>

The substrate with built-in electronic components according to any one of <1> to <3>, wherein, when the axis parallel to the direction in which the plurality of electronic components are arranged in top view from the first surface side is determined, there is a point at which a difference in the angle formed by the axis and the one side of each of the electronic components between adjacent electronic components of the plurality of electronic components is 5° or more and 45° or less.

<5>

The substrate with built-in electronic components according to any one of <1> to <4>, wherein, when the axis parallel to the direction in which the plurality of electronic components are arranged in top view from the first surface side is determined, a standard deviation of the angle formed by the axis and the one side of each of the electronic components is 5° or more.

<6>

The substrate with built-in electronic components according to any one of <1> to <5>, wherein center-to-center distances between the plurality of electronic components in top view from the first surface side are substantially identical to each other.

<7>

The substrate with built-in electronic components according to any one of <1> to <6>, wherein the plurality of electronic components are staggered in top view from the first surface side.

<8>

The substrate with built-in electronic components according to any one of <1> to <6>, wherein the plurality of electronic components are disposed in a grid pattern in top view from the first surface side.

<9>

The substrate with built-in electronic components according to any one of <1> to <8>, wherein the insulator has a plurality of cavities and each of the electronic components is disposed in a respective one of the cavities.

<10>

The substrate with built-in electronic components according to <9>, wherein the cavities are circular in top view from the first surface side.

<11>

The substrate with built-in electronic components according to <9>, wherein the cavities are rectangular in top view from the first surface side.

<12>

The substrate with built-in electronic components according to any one of <9> to <11>, wherein portions of the cavities around the electronic components are encapsulated with an encapsulating material.

<13>

The substrate with built-in electronic components according to any one of <1> to <12>, wherein a via conductor is connected to a center of a top surface of the first electrode on the first surface side and/or a center of a bottom surface of the second electrode on a second surface side.
10 insulating substrate (insulator)
11 first surface
12 second surface
15, 15A, 15B, 15C, 16 cavity
20, 20A, 20B, 20C electronic component
21 first electrode
22 second electrode
23A, 23B, 23C one side of electronic component
30 encapsulating material (insulator)
31 first surface of encapsulating material
32 second surface of encapsulating material
33 via hole
40 first via conductor
50 second via conductor
60 first buildup layer (rewiring layer)
61 insulating layer
62 conductor wiring
70 second buildup layer (rewiring layer)
71 insulating layer
72 conductor wiring
80 adhesive sheet
100, 101, 102, 103 substrate with built-in electronic components

1. A substrate with built-in electronic components, comprising:
an insulator having a first surface and a second surface facing away from the first surface; and
a plurality of electronic components built into the insulator,
wherein each of the electronic components includes a first electrode disposed in a first direction toward the first surface of the insulator and a second electrode disposed in a second direction opposite to the first direction,
each of the electronic components is rectangular in a top view from the first surface, and
rectangles of the plurality of electronic components in the top view from the first surface are irregularly disposed.

2. The substrate with built-in electronic components according to claim 1,
wherein, when an axis parallel to a direction in which the plurality of electronic components are arranged in the top view from the first surface is determined, there is a point at which an angle formed by the axis and one side of each of the electronic components differs between adjacent electronic components of the plurality of electronic components.

3. The substrate with built-in electronic components according to claim 1,
wherein, when the axis parallel to the direction in which the plurality of electronic components are arranged in the top view from the first surface is determined, an average angle of angles formed by the axis and the one side of each of the electronic components is 5° or more and 40° or less.

4. The substrate with built-in electronic components according to claim 1,
wherein, when the axis parallel to the direction in which the plurality of electronic components are arranged in the top view from the first surface is determined, there is a point at which a difference in the angle formed by the axis and the one side of each of the electronic components between adjacent electronic components of the plurality of electronic components is 5° or more and 45° or less.

5. The substrate with built-in electronic components according to claim 1,
wherein, when the axis parallel to the direction in which the plurality of electronic components are arranged in the top view from the first surface is determined, a standard deviation of the angle formed by the axis and the one side of each of the electronic components is 5° or more.

6. The substrate with built-in electronic components according to claim 1,
wherein center-to-center distances between the plurality of electronic components in the top view from the first surface are substantially identical to each other.

7. The substrate with built-in electronic components according to claim 1,
wherein the plurality of electronic components are staggered in the top view from the first surface.

8. The substrate with built-in electronic components according to claim 1,
wherein the plurality of electronic components are disposed in a grid pattern in the top view from the first surface.

9. The substrate with built-in electronic components according to claim 1,
wherein the insulator has a plurality of cavities and each of the electronic components is disposed in a respective one of the cavities.

10. The substrate with built-in electronic components according to claim 9,
wherein the cavities are circular in the top view from the first surface.

11. The substrate with built-in electronic components according to claim 9,
wherein the cavities are rectangular in the top view from the first surface.

12. The substrate with built-in electronic components according to claim 9,
wherein portions of the cavities around the electronic components are encapsulated with an encapsulating material.

13. The substrate with built-in electronic components according to claim 1,
wherein a via conductor is connected to a center of a top surface of the first electrode located closer to the first surface and/or a center of a bottom surface of the second electrode located closer to a second surface.

14. The substrate with built-in electronic components according to claim 2,
wherein, when an axis parallel to a direction in which the plurality of electronic components are arranged in the top view from the first surface is determined, there is a point at which an angle formed by the axis and one side of each of the electronic components differs between adjacent electronic components of the plurality of electronic components.

15. The substrate with built-in electronic components according to claim 2,
wherein, when the axis parallel to the direction in which the plurality of electronic components are arranged in the top view from the first surface is determined, there is a point at which a difference in the angle formed by the axis and the one side of each of the electronic components between adjacent electronic components of the plurality of electronic components is 5° or more and 45° or less.

16. The substrate with built-in electronic components according to claim 3,
wherein, when the axis parallel to the direction in which the plurality of electronic components are arranged in the top view from the first surface is determined, there is a point at which a difference in the angle formed by the axis and the one side of each of the electronic components between adjacent electronic components of the plurality of electronic components is 5° or more and 45° or less.

17. The substrate with built-in electronic components according to claim 2,
wherein, when the axis parallel to the direction in which the plurality of electronic components are arranged in the top view from the first surface is determined, a standard deviation of the angle formed by the axis and the one side of each of the electronic components is 5° or more.

18. The substrate with built-in electronic components according to claim 3,
wherein, when the axis parallel to the direction in which the plurality of electronic components are arranged in the top view from the first surface is determined, a standard deviation of the angle formed by the axis and the one side of each of the electronic components is 5° or more.

19. The substrate with built-in electronic components according to claim 4,
wherein, when the axis parallel to the direction in which the plurality of electronic components are arranged in the top view from the first surface is determined, a standard deviation of the angle formed by the axis and the one side of each of the electronic components is 5° or more.

20. The substrate with built-in electronic components according to claim 2,
wherein center-to-center distances between the plurality of electronic components in the top view from the first surface are substantially identical to each other.
